(19) United States
(12) Patent Application Publication
(10) Pub. No.: US 2003/0127248 A1
(43) Pub. Date: Jul. 10, 2003

(54) Protection outer layer for circuit boards and method for making the same

(76) Inventor: Gorden Kuo, Taichung Hsieh (TW)

Correspondence Address: Alan D. Kamrath, Rider, Bennett, Egan & Arundel, LLP, 333 South Seventh Street, Suite 2000, Minneapolis, MN, 55402, US

(21) Appl. No.: 10/046,116

(22) Filed: Jan. 7, 2002

(51) Int. Cl. H05K 1/03; B32B 27/00; B32B 27/40; B32B 27/38

(52) U.S. Cl. 174/256; 174/258; 428/446; 428/423.1; 427/96

(57) ABSTRACT

A circuit board is coated by a protection layer made of poly-urethane resin with crosslinking agent, silicon resin with crosslinking agent, or Epoxy Resin and crosslinking agent. The protection layer is poured in a cave of a mold set and the circuit board is positioned in the cave. The protection layer is completely coated or partially coated onto the circuit board. The protection layer is a water proof soft material and absorbs vibration so as to provide a better protection feature of the circuit board.

### FIELD OF THE INVENTION

The present invention relates to a protection outer layer coated on an outer surface of a circuit board so as to provide anti-vibration and water-proof features.

### BACKGROUND OF THE INVENTION

A conventional circuit board such as the digital touch panel as shown in FIG. 1, the cellular phone as shown in FIGS. 2 and 3, or the memory card for video games as shown in FIGS. 4 and 5, is composed of a top casing 91, a bottom casing 92 and a circuit board 93 which is sandwiched between the top casing 91 and the bottom casing 92. The top casing 91 and the bottom casing 92 are connected with each other by screws, snapping or gluing. The top casing 91 and the bottom casing 92 have to be made separately by different molds, and the assembling processes are time-consuming and affect the preparation time. The top casing 91 and the bottom casing 92 are made of plastic material which could be damaged when the products drop on the ground. Besides, the conventional casings do not have water-proof feature so that once the cellular phone drop into water, the circuit is short and functionless. Together with the decline of the price of the electronic products, the plastic casings are not an appropriate choice for cooperating with the electronic products.

The present invention intends to provide an outer layer made of polyacrylic resin or silicon resin which is coated on the circuit board so as to provide anti-vibration and water-proof features.

### SUMMARY OF THE INVENTION

The present invention relates to a circuit board with a protection outer layer coated thereon and the protection layer is made of soft material and is able to absorb shocks and water proof.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is an exploded view to show a conventional digital touch panel;

FIG. 2 is a perspective view to show a conventional cellular phone;

FIG. 3 is an exploded view to show the conventional cellular phone;

FIG. 4 is a perspective view to show a conventional memory card;

FIG. 5 is a cross sectional view to show the conventional memory card.

FIG. 6 is a perspective view to show a digital touch panel of the present invention;

FIG. 7 is a cross sectional view to show the digital touch panel of the present invention;

FIG. 8 is a cross sectional view to show the digital touch panel of the present invention from another direction;

FIG. 9 is an exploded view to show a circuit board protected by two aluminum foils;

FIG. 10 shows the circuit board of a digital touch panel is protected by the protection layer;

FIG. 11 shows that the protection layer of the present invention is used on a memory card;

FIGS. 12 to 14 show the steps of the circuit board is coated with the protection layer in a mold set;

FIG. 15 shows a cellular phone is protected by the protection layer of the present invention, and FIG. 16 shows the cellular phone is put in the cave of the mold set.

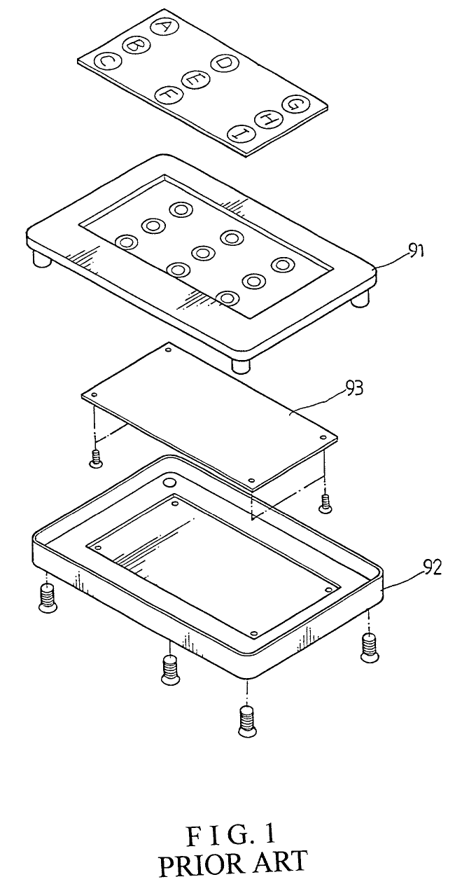

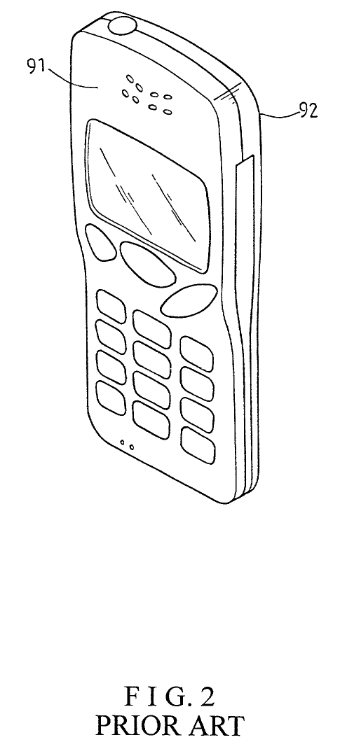

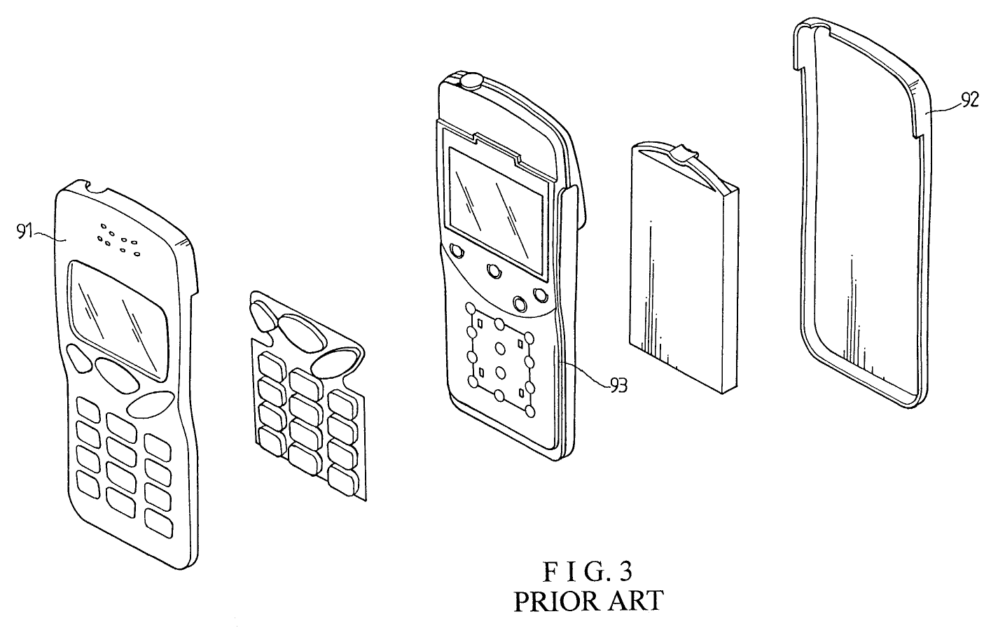

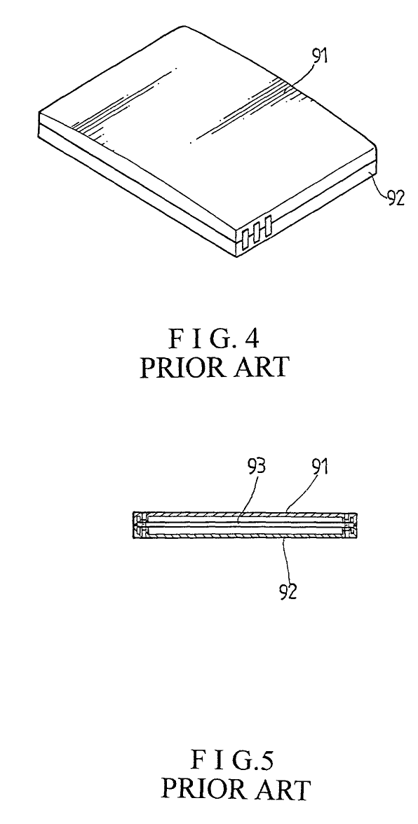

### DETAILED DESCRIPTION OF THE PREFERRED EMBODIMENTS

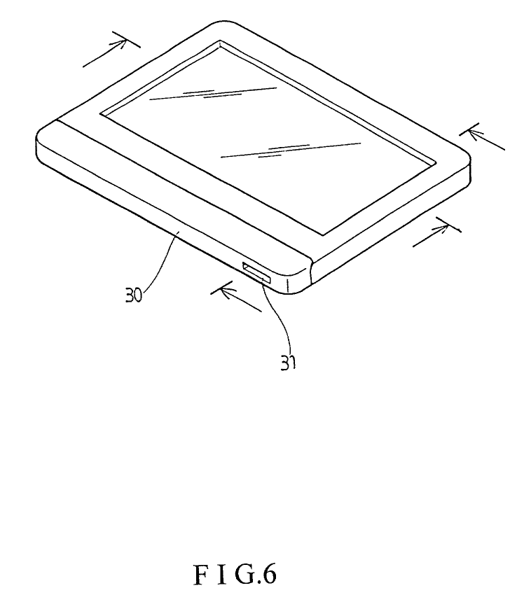

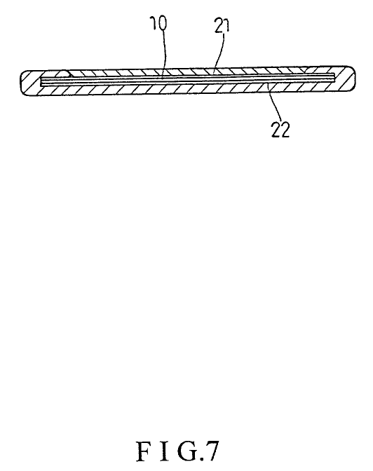

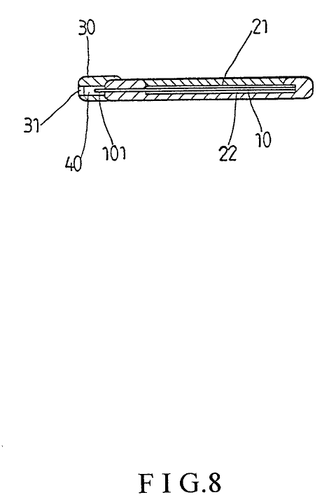

Referring to FIGS. 6 to 8, a digital touch panel for example in this embodiment includes a circuit board 10 which is sandwiched between a protection layer of the present invention. The circuit board 10 has functions of control and calculation. The protection layer is completely or partially coated on an outer surface of the circuit board 10 and is integral with the circuit board 10. A sidebar 30 is connected to a side of the touch panel and an opening defined in the protection layer so that a connection port 101 of the circuit board 10 is located in the opening. The sidebar 30 has another circuit board 40 received therein which is electronically connected to the circuit board 10. An accessing hole 31 is defined in the sidebar 30 so as to access the circuit board 40.

The protection layer is made of poly-urethane resin with crosslinking agent, silicon resin with crosslinking agent, or Epoxy Resin and crosslinking agent. In this embodiment, polycol Ether is taken to be mixed with MDI at room temperature and the combination is fluid status in room temperature. The protection layer material is poured in the mold set which is described hereinafter to become the protection layer coated on the circuit board 10. The protection layer is soft and can be deformed when being pressed. The protection layer is able to absorb shocks and vibration, and is water proof so that the circuit board 10 is protected by the protection layer. The protection later may also be made by mixing Polycol Ether and MDI at a certain ratio.

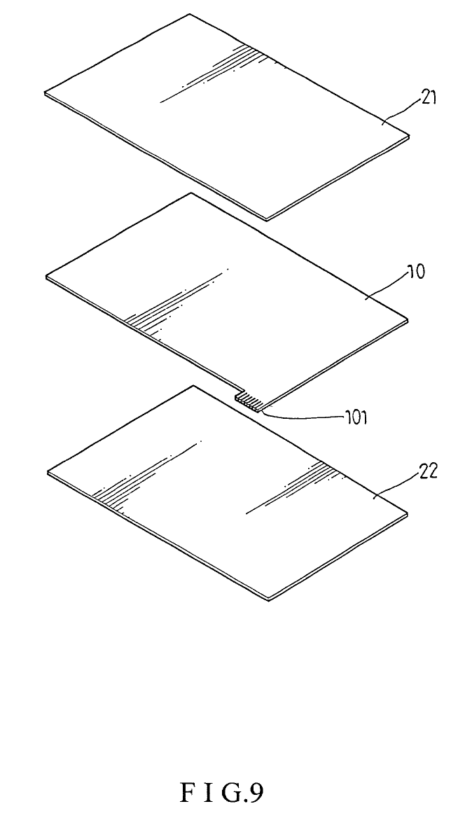

A FIG. 9 shows that two layers of aluminum foils 21, 22 are respectively connected to a top and a bottom of the circuit board 10 so as to reduce interference from outside signals. The two aluminum foils 21, 22 are embraced by the protection layer.

The circuit board 10 can be any type of electronic piece such as print circuit boards, circuit membranes, and integrated circuit boards.

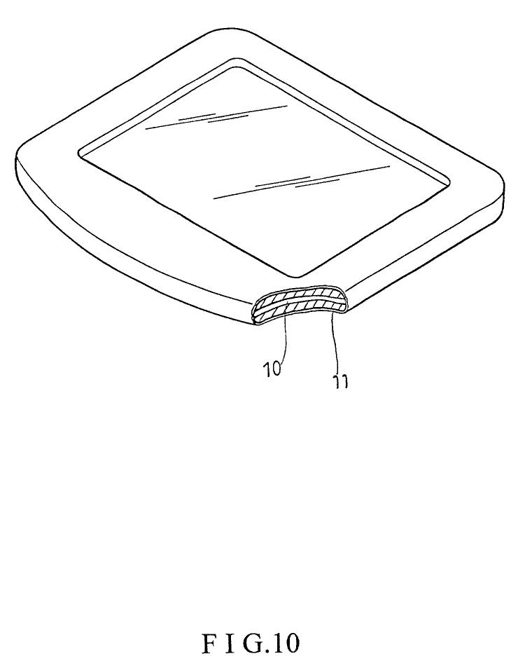

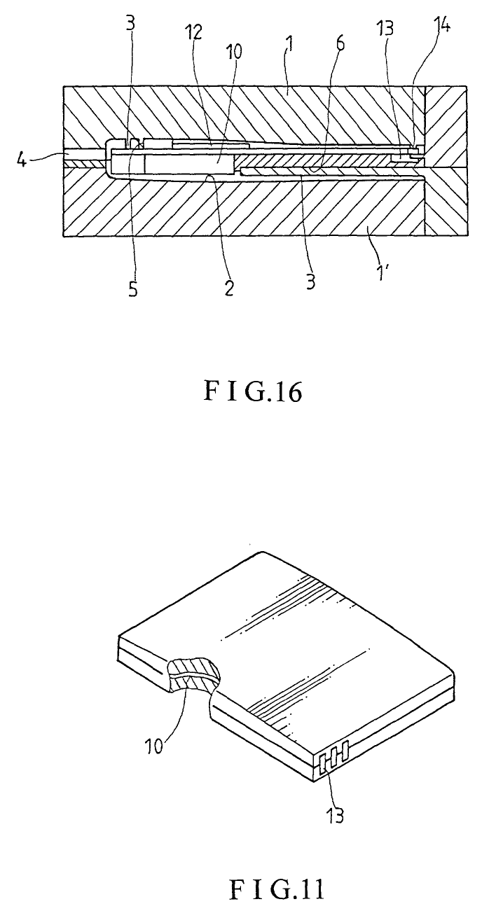

As shown in FIG. 10, the protection layer can be treated to have a film 11 on an outer surface thereof and the film 11 is made to have some characters to meet specific needs or acquires such as to prevent from being scraped or attached by dust. FIG. 11 shows the protection layer of the present invention is used on the memory card wherein the connection ports 13 are not sealed by the protection layer.

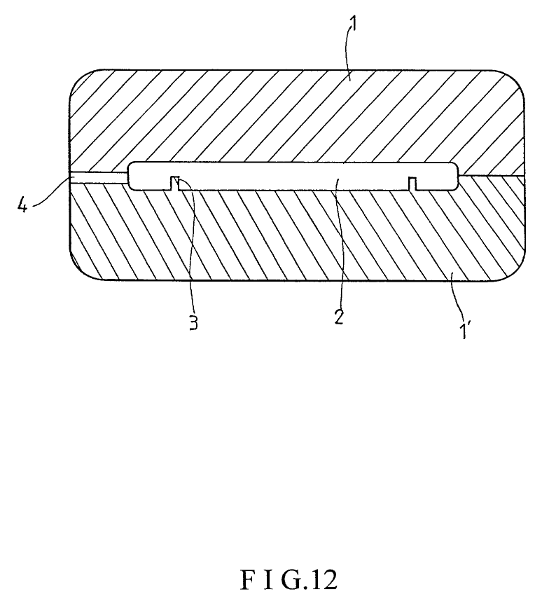

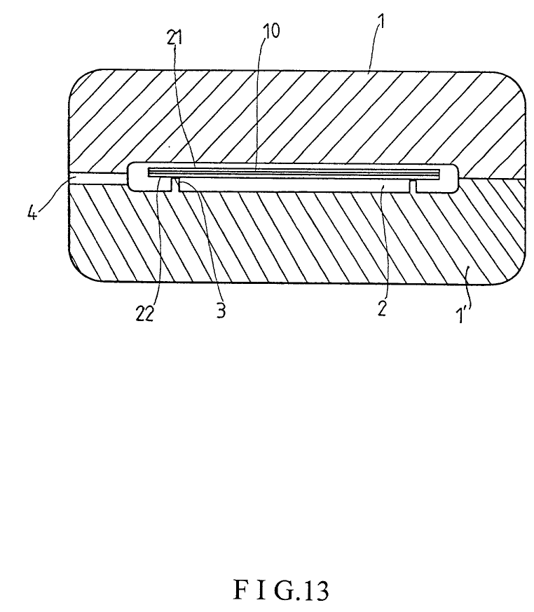

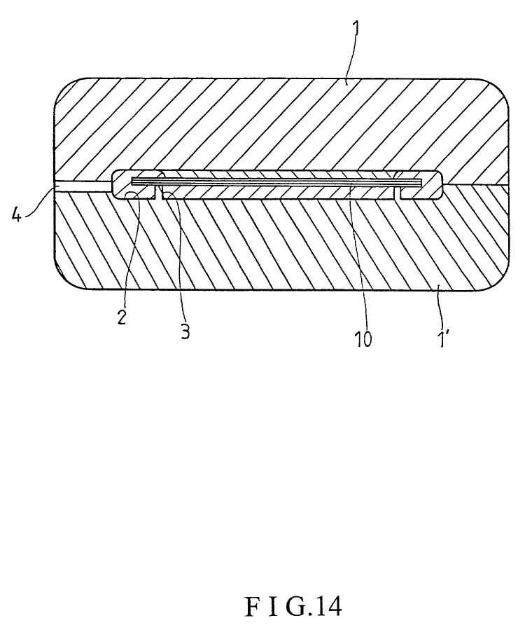

Referring to FIGS. 12 to 14, a method for making a protection layer coated on a circuit board 10 comprises the following steps:

step 1: preparing a circuit board 10 that has functions of control and calculation;

step 2: preparing a top mold 1 and a bottom mold 1′, a cave 2 defined between the top mold 1 and the bottom mold 1′;

step 3: putting the circuit board 10 in the cave 2 defined between the top mold 1 and the bottom mold 1′;

step 4: pouring protection layer material into the cave 2 via a pouring path 4 between the top mold 1 and the bottom mold 1′, the protection layer material coated to the circuit board 10 and solidified, the soft protection layer being able to deformed after being pressed, and

step 5: removing the top mold 1 and the bottom mold 1′ and picking the circuit board 10 coated with the protection layer.

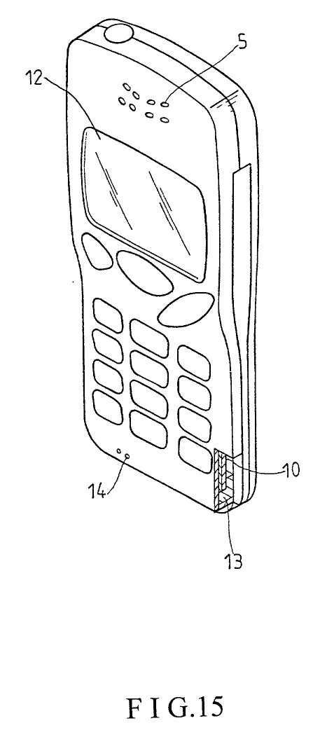

FIGS. 15 and 16 show that a circuit board 10 of a cellular phone is put in the cave 2 of the mold set 1 and 1′. The receiving end 5, the microphone portion 14, the window 12 and the battery space 6 of the cellular phone are properly covered by the mold set 1 and 1′. The material of the protection layer is then poured in the cave 2 via the pouring path 4. The circuit board 10 of the cellular phone is protected by the protection layer and the cellular phone is anti-shocks and water proof.

While we have shown and described the embodiment in accordance with the present invention, it should be clear to those skilled in the art that further embodiments may be made without departing from the scope of the present invention.

What is claimed is:

1. An electronic product with a protection outer layer, comprising:
a circuit board which has functions of controlling and calculation;
a soft protection layer coated on an outer surface of the circuit board, said soft protection layer being integral with the circuit board.

2. The circuit board as claimed in claim 1 further comprising a film coated on the protection layer.

3. The circuit board as claimed in claim 1 wherein the circuit board is completely coated by the protection layer.

4. The circuit board as claimed in claim 1 wherein the circuit board is partially coated by the protection layer.

5. The circuit board as claimed in claim 1 wherein the protection layer is made of poly-urethane resin and crosslinking agent.

6. The circuit board as claimed in claim 1 wherein the protection layer is made of Silicon resin and crosslinking agent.

7. The circuit board as claimed in claim 1 wherein the protection layer is made of Epoxy Resin and crosslinking agent.

8. A method for making a protection layer coated on a circuit board, comprising the following steps:
step 1: preparing a circuit board that has functions of controlling and calculation;
step 2: preparing a top mold and a bottom mold, a cave defined between the top mold and the bottom mold;
step 3: putting the circuit board in the cave defined between the top mold and the bottom mold;
step 4: pouring protection layer material into the cave via a pouring path between the top mold and the bottom mold, the protection layer material coated to the circuit board and solidified, the soft protection layer being deformed after being pressed, and
step 5: removing the top mold and the bottom mold and picking the circuit board coated with the protection layer.

9. The circuit board as claimed in claim 8 wherein the protection layer is made of poly-urethane and crosslinking agent.

10. The circuit board as claimed in claim 8 wherein the protection layer is made of Silicon resin and crosslinking agent.

11. The circuit board as claimed in claim 8 wherein the protection layer is made of Epoxy Resin and crosslinking agent.

12. The method as claimed in claim 8 further comprising two positioning protrusions extending from an inside of the cave and the circuit board engaged with the protrusions.

13. The method as claimed in claim 8 further comprising a film coated on the protection layer.

14. The method as claimed in claim 8 wherein the protection layer material is formed by mixing in fluid status at room temperature.
